(19) United States
(12) Patent Application Publication
(10) Pub. No.: US 2026/0353952 A1
(43) Pub. Date: Nov. 5, 2026

(54) Display Device And Electronic Device Including The Same

(71) Applicant: Samsung Display Co., Ltd., Yongin-si (KR)

(72) Inventors: Doyeong Park, Yongin-si (KR); Donghee Shin, Yongin-si (KR)

(73) Assignee: Samsung Display Co., Ltd., Yongin-si (KR)

(21) Appl. No.: 19/663,349

(22) Filed: Apr. 30, 2026

(30) Foreign Application Priority Data
May 2, 2025 (KR) 10-2025-0058485

(51) Int. Cl. H10K 59/131

(52) U.S. Cl. CPC H10K 59/131

(57) ABSTRACT

The disclosure provides a display device that includes a display panel with a substrate. In one aspect, the disclosure provides an electronic device that includes the display device. In one aspect, a first horizontal connection line is disposed on the substrate, extending in a first direction and including a first connection portion. A second horizontal connection line is disposed adjacent to the first horizontal connection line and includes a second-first horizontal connection line and a second-second horizontal connection line. The second-first horizontal connection line and the second-second horizontal connection line extend in the first direction. In one aspect, a first bridge line electrically connects the second-first horizontal connection line to the second-second horizontal connection line. In one aspect, the first horizontal connection line and the first vertical connection line are electrically connected to each other through a first contact hole arranged in the first connection portion.

### CROSS-REFERENCE TO RELATED APPLICATION

This application claims priority to and the benefit of Korean Patent Application No. 10-2025-0058485, filed on May 2, 2025, the disclosure of which is incorporated by reference herein in its entirety.

### TECHNICAL FIELD

The present disclosure relates to a display device and an electronic device. More particularly, the present disclosure relates to a display device with improved reliability and quality, and an electronic device that includes such a display device.

### BACKGROUND

A display device visually displays data. The display device may provide images using light-emitting diodes. Display devices are becoming more diverse in their uses, and various designs have been attempted to improve the quality of display devices. As such, electronic devices may include a display device for providing images.

Accordingly, there is a need for display devices that have improved image quality as well as improved reliability.

### BRIEF SUMMARY

The disclosure is intended to solve various problems including the above-mentioned problems and aims to provide a display device with improved reliability and quality. The present disclosure also provides an electronic device that includes the contemplated display device. However, these tasks are just examples and the scope of the disclosure is not limited thereby.

Additional aspects will be set forth in part in the description which follows and, in part, will be apparent from the description, or may be learned by practice of the presented embodiments of the disclosure.

In some embodiments, a display device includes a display panel, the display panel comprising a substrate; a first horizontal connection line disposed on the substrate, extending in a first direction, and including a first connection portion; a first vertical connection line disposed on the substrate, extending in a second direction intersecting the first direction and including the first connection portion; a second horizontal connection line disposed on the substrate adjacent to the first horizontal connection line, the second horizontal connection line comprising a second-first horizontal connection line and a second-second horizontal connection line, the second-first horizontal connection line and a second-second horizontal connection line extending in the first direction; and a first bridge line electrically connecting the second-first horizontal connection line and the second-second horizontal connection line, wherein the first horizontal connection line and the first vertical connection line are electrically connected through a first contact hole arranged in the first connection portion.

In some embodiments, the first connection portion comprises a portion where at least a portion of the first horizontal connection line and at least a portion of the first vertical connection line overlap.

In some embodiments, a data signal is applied to the first vertical connection line.

In some embodiments, the data signal applied to the first vertical connection line is also applied to the first horizontal connection line through the first contact hole.

In some embodiments, the first bridge line overlaps at least a portion of the first connection portion.

In some embodiments, the first bridge line and the second-first horizontal connection line are electrically connected through the second contact hole.

In some embodiments, the first bridge line and the second-second horizontal connection line are electrically connected through a third contact hole.

In some embodiments, the display device further includes a pixel unit disposed on the substrate and including eight subpixels.

In some embodiments, the eight subpixels included in the pixel unit are arranged in a pentile array.

In some embodiments, each subpixel circuit of eight subpixel circuits is respectively electrically connected to a subpixel of the eight subpixels included in the pixel unit, and the eight subpixels are arranged in the first direction.

In some embodiments, the device further includes: a third horizontal connection line disposed on the substrate, extending in the first direction and including an unconnected portion; a second vertical connection line disposed on the substrate, extending in the second direction and including the unconnected portion; a fourth horizontal connection line disposed on the substrate adjacent to the third horizontal connection line, the fourth horizontal connection line comprising a fourth-first horizontal connection line and a fourth-second horizontal connection line, the fourth-first horizontal connection line and the fourth-second horizontal connection line extending in the first direction; and a second bridge line electrically connecting the fourth-first horizontal connection line and the fourth-second horizontal connection line.

In some embodiments, the unconnected portion is a portion in which at least a portion of the third horizontal connection line and at least a portion of the second vertical connection line overlap.

In some embodiments, the second bridge line overlaps at least a portion of the unconnected portion.

In some embodiments, the second bridge line and the fourth-first horizontal connection line are electrically connected through a fourth contact hole.

In some embodiments, the second bridge line and the fourth-second horizontal connection line are electrically connected through a fifth contact hole.

In some embodiments, an electronic device includes a display panel; and a lower cover forming an appearance and having an opening exposing a portion of the display panel on a front surface, wherein the display panel comprises: a substrate; a first horizontal connection line disposed on the substrate, extending in the first direction, and including a first connection portion; a first vertical connection line disposed on the substrate, extending in the second direction intersecting the first direction and including the first connection portion; a second vertical connection line disposed on the substrate comprising a second-first vertical connection line and a second-second vertical connection line, and the second vertical connection line being adjacent to the first vertical connection line, and the second vertical connection line extending in the second direction; and a first bridge line electrically connecting the second-first vertical connection line to the second-second vertical connection line, wherein the first horizontal connection line and the first vertical connection line are electrically connected to each other through a first contact hole arranged in the first connection portion.

In some embodiments, the first connection portion comprises a portion in which at least a portion of the first horizontal connection line and at least a portion of the first vertical connection line overlap.

In some embodiments, a data signal is applied to the first vertical connection line, and the data signal applied to the first vertical connection line is also applied to the first horizontal connection line through the first contact hole.

In some embodiments, the first bridge line and the second-first vertical connection line are electrically connected through a second contact hole.

In some embodiments, the first bridge line and the second-second vertical connection line are electrically connected through an third contact hole.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of a central processing unit according to an embodiment of the present disclosure;

FIG. 2 shows schematic diagrams of electronic devices according to various embodiments of the present disclosure;

FIG. 3 is a schematic plan view of a display panel according to an embodiment of the present disclosure;

FIG. 4 is a schematic equivalent circuit diagram of one subpixel of a display panel according to an embodiment of the present disclosure;

FIG. 5 is a schematic cross-sectional view of a display panel according to an embodiment of the present disclosure;

FIG. 6 is a schematic plan view of a structure in which pixels of a display panel are arranged according to an embodiment of the present disclosure;

FIG. 7 is a schematic plan view of a structure in which subpixel circuits are arranged according to an embodiment of the present disclosure;

FIG. 8 is a schematic plan view of connection lines arranged in a second area of a display panel according to an embodiment of the present disclosure;

FIG. 9 is a schematic enlarged view of a third connection area shown in FIG. 8;

FIG. 10 is a schematic enlarged view of a connection area in a comparative example;

FIG. 11 is a schematic cross-sectional view of the display panel illustrated in FIG. 9 taken along line I-I';

FIG. 12 is a schematic cross-sectional view of the display panel illustrated in FIG. 9 taken along line II-II';

FIG. 13 is a schematic enlarged view of a first unconnected region illustrated in FIG. 8; and

FIG. 14 is a schematic enlarged view of a connection area according to an embodiment of the present disclosure.

### DETAILED DESCRIPTION

While specific embodiments are shown in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

In addition, spatially relative terms, such as “below”, “lower”, “above”, “upper” and the like, may be used herein for ease of description to describe one element or feature’s relationship to another element or feature as shown in the figures.

Hereinafter, embodiments of disclosure will be described in detail with reference to the attached drawings. When describing with reference to the drawings, identical or corresponding components are given the same drawing reference numerals and redundant descriptions thereof are omitted.

In the examples below, the terms first, second, etc. are not used in a limiting sense but are used for the purpose of distinguishing one component from another. As such, in the present disclosure, it will be understood that when a first element (or area, layer, or portion) is referred to as being "on", "connected to" or "coupled to" a second element or layer, the first element can be directly on, connected or coupled to the second element or layer or intervening elements or layers may be present and disposed in between the first and second elements.

In the examples below, singular expressions include plural expressions unless the context clearly indicates otherwise.

In the examples below, terms such as “include” or “have” mean that a feature or component described in the specification is present, and do not exclude in advance the possibility that one or more other features or components may be added.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the following examples, when a part such as a film, region, component, etc. is said to be on or above another part, it includes not only the case where it is directly on top of the other part, but also the case where another film, region, component, etc. is interposed in between.

In the drawings, sizes of components may be exaggerated or reduced for convenience of explanation. For example, a size and thickness of each component shown in the drawing are arbitrarily shown for convenience of explanation, and thus the present implementation of the teachings of the present disclosure are not necessarily limited to what is shown.

Additionally, the terms “about,” “generally,” and “substantially” are intended to mean, and a person of ordinary skill would understand them to mean that slight deviations from absolute are included within the scope of the term so modified.

In some embodiments, where the implementation is otherwise feasible, specific process sequences may be performed in a different order than described. For example, two processes described sequentially may be performed substantially simultaneously, or may proceed in the reverse order from that described.

In this specification, “A and/or B” refers to either A, B, or both A and B. And, “at least one of A and B” indicates the case where it is A, or B, or both A and B.

In the following examples, when it is said that a film, region, component, etc. are connected, it includes a case where the films, regions, or components are directly connected, and/or a case where other films, regions, or components are interposed between the films, regions, or components and are indirectly connected. For example, when it is said in this specification that a film, region, component, etc. are electrically connected, it refers to a case where the film, region, component, etc. are directly electrically connected, and/or a case where another film, region, component, etc. is interposed between them and is indirectly electrically connected.

The x-axis, y-axis, and z-axis are not limited to the three axes on the orthogonal coordinate system and may be interpreted in a broad sense that includes them. For example, the x-axis, y-axis, and z-axis may be orthogonal to each other, but they may also refer to different directions that are not orthogonal to each other.

A display device according to an embodiment may be included in various electronic devices. In some aspect, an electronic device according to an embodiment includes the display device described above, and may further include a module or device having additional functions in addition to the display device.

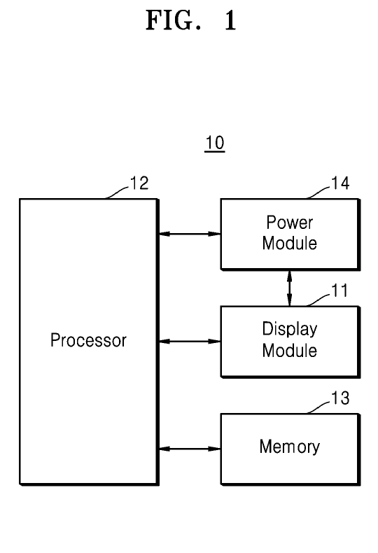

FIG. 1 is a block diagram of a central processing unit according to an embodiment.

Referring to FIG. 1, an electronic device 10 according to an embodiment may include a display module 11, a processor 12, a memory 13, and a power module 14.

The processor 12 may include at least one of a central processing unit CPU, an application processor AP, a graphic processing unit GPU, a communication processor CP, an image signal processor ISP, and a controller.

Data information necessary for the operation of the processor 12 or the display module 11 may be stored in the memory 15. When the processor 12 executes an application stored in the memory 15, an image data signal and/or an input control signal is transmitted to the display module 11, and the display module 11 may process the received signal and output image information through a display panel.

The power module 14 may include a power supply module, such as a power adapter or a battery device, and a power conversion module that converts power supplied by the power supply module to generate power required for the operation of the electronic device 10.

At least one of the components of the above-described electronic device may be included in a display device according to the above-described embodiments. Additionally, some of the individual modules functionally included within a module may be included within the display device, while others may be provided separately from the display device. For example, the display device may include the display module 11, and the processor 12, the memory 13 and the power module 14 may be provided in the form of other devices within the electronic device other than the display device.

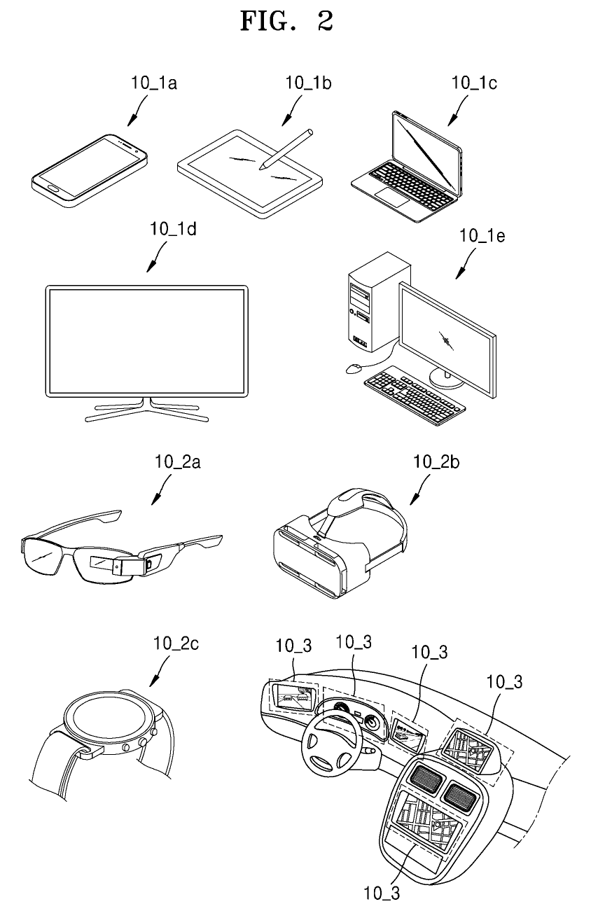

FIG. 2 shows schematic diagrams of electronic devices according to various embodiments.

Referring to FIG. 2, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and car instrument panel.

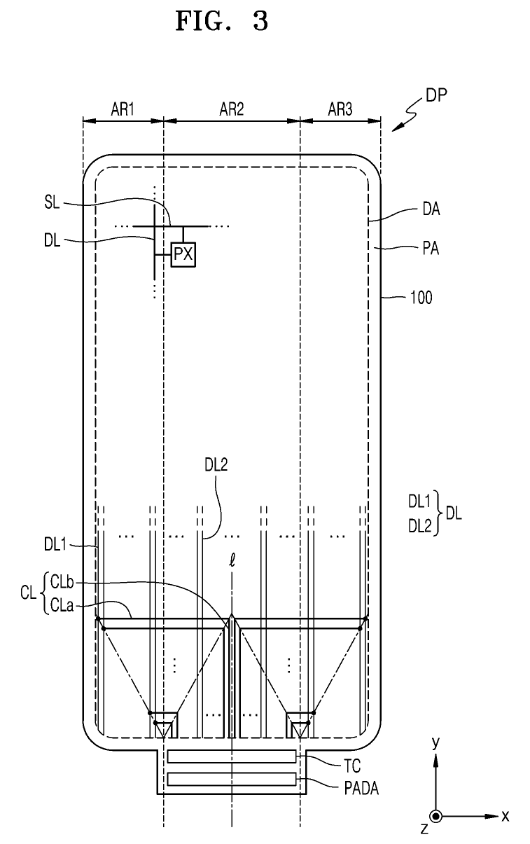

FIG. 3 is a schematic plan view of a display panel according to an embodiment.

Referring to FIG. 3, a display panel DP may include a display area DA and a peripheral area PA arranged around the display area DA. The display panel DP may provide an image to the outside using light emitted from the display area DA. Because the display panel DP includes a substrate 100, it may be said that the substrate 100 includes the display area DA and the peripheral area PA.

The substrate 100 may include various materials such as glass, metal, or plastic. According to an embodiment, the substrate 100 may include a flexible material. The flexible material refers to a material that may be easily bent, curved, folded, or rolled. The substrate 100 including the flexible material may include ultra-thin glass, metal or plastic.

Subpixels PX equipped with various display elements, such as organic light-emitting diode OLED, may be arranged in the display area DA of the substrate 100. According to an embodiment, the subpixels PX may be arranged in a pentile array to implement an image.

The display area DA may have a planar shape such as a rounded rectangle as illustrated in FIG. 3. In another embodiment, the planar shape of the display area DA may be a polygonal shape such as a square, triangle, pentagon, or hexagon, or a circular shape, an oval shape, or an irregular shape.

The peripheral area PA may surround the display area DA. The peripheral area PA is an area where the subpixels PX are not arranged, and various wires that transmit electrical signals to be applied to the display area DA, and a pad area PADA including pads to which printed circuit boards or driver IC chips are attached may be located. The pads may be electrically connected to a data driver.

In one embodiment, the data driver that supplies a data signal may be disposed on a film that is electrically connected to pads on the pad area PADA in a COF (Chip On Film) manner. According to another embodiment, the data driver may be placed directly on the substrate 100 in a COG (Chip On Glass) or COP (Chip On Plastic) manner.

A test circuit TC may be disposed in the peripheral area PA. By driving the test circuit TC, it is possible to check whether the subpixels PX of the display area DA are operating normally. Such the test circuit TC may include a plurality of transistors, a plurality of voltage wires, and a plurality of gate wires.

Meanwhile, signal lines capable of applying electrical signals to the subpixels PX may be disposed in the display area DA.

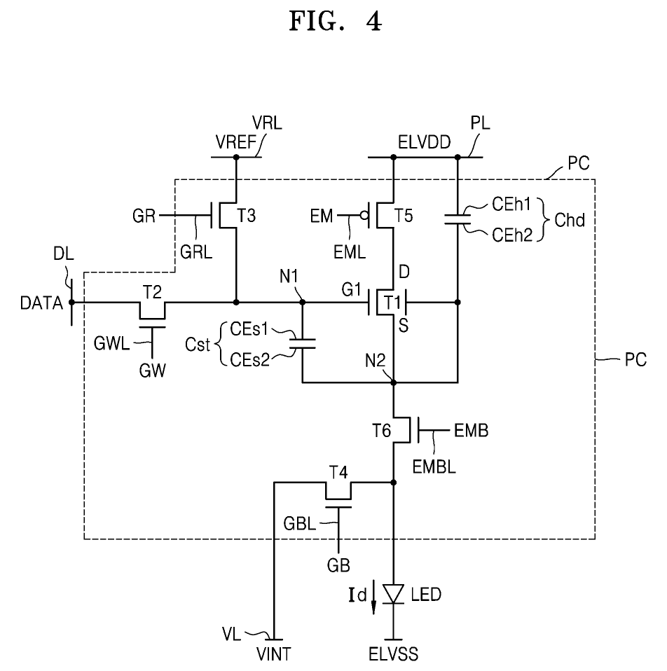

As described later in FIG. 4, each of the subpixels PX may include a display element and a subpixel circuit for driving the display element. For example, the display element may be an organic light-emitting diode, and the subpixel circuit may include transistors and storage capacitors, etc. The subpixels PXs may include first subpixels emitting light of a first color, second subpixels emitting light of a second color, and third subpixels emitting light of a third color.

Signal lines capable of applying electrical signals to the subpixels PX may include scan lines SL, data lines DL, etc. Each of the data lines DL may extend in the column direction (e.g., ± y direction), and each of the scan lines SL may extend in the row direction (e.g., ± x direction).

The scan lines SL may be arranged in, for example, multiple rows to transmit scan signals to the subpixels PX, and the data lines DL may be arranged in, for example, multiple columns to transmit data signals to the subpixels PX. Each of the subpixels PX may be connected to at least one corresponding scan line SL among the scan lines SL and to a corresponding data line DL among the data lines DL.

In one embodiment, the display panel 10 may include a first region AR1, a second region AR2, and a third region AR3. The first region AR1 and the third region AR3 may be separated from each other with the second region AR2 disposed therebetween. Of course, because the display panel 10 includes the substrate 100, it may be said that the substrate 100 has the first region AR1, the second region AR2, and the third region AR3.

The first area AR1, the second area AR2, and the third area AR3 may each overlap at least a portion of the display area DA. The first region AR1, the second region AR2, and the third region AR3 may each overlap at least a portion of the peripheral region PA.

A part of the first region AR1 and the second region AR2 arranged on a left side of an imaginary line ℓ passing through an approximate center of the row direction (e.g., ± x direction) of the display panel 10, and another part of the second region AR2 and the third region AR3 located on a right side of the imaginary line ℓ may be approximately symmetrical left and right with respect to the imaginary line ℓ.

In the following, the description will be based on a part of the first area AR1 and the second area AR2 arranged on the left side of the virtual line ℓ, and the same description may be applied to another part of the second area AR2 arranged on the right side of the virtual line ℓ and the third area AR3.

The data lines DL may include first data lines DL1 extending along the column direction (e.g., ± y direction) in the first region AR1, and second data lines DL2 extending along the column direction (e.g., ± y direction) in the second region AR2, as illustrated in FIG. 3.

The first data lines DL1 may each be connected to the connection lines CL. The connection lines CL may transmit electrical signals supplied from pads arranged in the pad area PADA to the first data lines DL1, respectively. For example, data signals may be applied to each of the first data lines DL1 through the connecting lines CL. In this case, the fan-out wiring connected to each of the first data lines DL1 may be omitted. Therefore, some of the peripheral area PA where fan-out wiring is disposed may be eliminated. Since an area of the peripheral area PA may be reduced by an area in which the fan-out wiring is arranged, a dead area of the display panel 10 may be reduced.

One end of each of the connection lines CL may be connected to a corresponding first data line DL1 among the first data lines DL1, and the other end of each of the connection lines CL may be connected to a corresponding pad among the pads of the pad area PADA. In one embodiment, when the other end of each of the connection lines CL is connected to a corresponding pad among the pads of the pad area PADA, it may be connected through a separate bridge line (not shown). For example, a bridge line may be a portion of a connection line CL that extends toward the peripheral area PA. As another example, the bridge line is a separate line disposed on a different layer from the connection line CL, and may be electrically connected to the connection line CL in the peripheral area PA.

Each of the connection lines CL may include a horizontal connection line CLa and a vertical connection line CLb.

Each horizontal connection line CLa of the connection lines CL may extend along the row direction (e.g., ± x direction) and be connected to the corresponding first data lines DL1, respectively. The horizontal connection line CLa of each of the connection lines CL may be parallel to the scan line SL.

At least a portion of the horizontal connecting line CLa of each of the connecting lines CL may overlap the first region AR1, and at least another portion of the horizontal connecting line CLa of each of the connecting lines CL may overlap the second region AR2.

The vertical connection line CLb of each of the connection lines CL may be arranged on a side of the imaginary line ℓ. As illustrated in FIG. 3, the vertical connection line CLb of each of the connection lines CL may overlap with the second region AR2, and thus may be arranged adjacent to the second data line DL2. Each vertical connection line CLb of the connection lines CL may extend along the thermal direction (e.g., ± y direction) away from the pad area PADA. The vertical connection line CLb of each of the connection lines CL may be parallel to the data line DL.

Second data lines DL2 may be data lines other than the first data lines DL1. The second data lines DL2 may be connected to corresponding pad among the pads in the pad area PADA.

In one embodiment, each of the second data lines DL2 may be connected to corresponding pad among the pads of the pad area PADA through a separate bridge line (not shown). For example, the bridge line may be a portion of the second data line DL2 that extends toward the peripheral area PA. As another example, the bridge line may be a separate line disposed on a different layer from the second data line DL2 and may be electrically connected to the second data line DL2 in the peripheral area PA.

FIG. 4 is a schematic equivalent circuit diagram of one subpixel of a display panel according to an embodiment.

Referring to FIG. 4, a subpixel circuit PC connected to a light emitting diode LED may include a plurality of transistors and at least one capacitor. For example, the sub-pixel circuit PC may include at least one driving transistor, at least one switching transistor, and at least one capacitor. For example, the sub-pixel circuit PC may include a first transistor T1, a second transistor T2, a third transistor T3, a fourth transistor T4, a fifth transistor T5, a sixth transistor T6, a storage capacitor Cst, and a hold capacitor Chd.

The first transistor T1 is a driving transistor that outputs a driving current corresponding to a data signal, and the second transistor T2, the third transistor T3, the fourth transistor T4, the fifth transistor T5, and the sixth transistor T6 may be switching transistors that transmit signals through on/off. A first terminal (first electrode) of each of the first transistor T1, the second transistor T2, the third transistor T3, the fourth transistor T4, the fifth transistor T5, and the sixth transistor T6 may be either a source region or a drain region, and a second terminal (second electrode) may be the other.

At least one of the first transistor T1, the second transistor T2, the third transistor T3, the fourth transistor T4, the fifth transistor T5, and the sixth transistor T6 may be a PMOS (p-channel MOSFET), and the rest may be NMOS (n-channel MOSFETs). For example, the fifth transistor T5 may be a PMOS, and the first transistor T1, the second transistor T2, the third transistor T3, the fourth transistor T4, and the sixth transistor T6 may be NMOS. Alternatively, the fifth transistor T5 and the sixth transistor T6 may be PMOS, and the first transistor T1, the second transistor T2, the third transistor T3, and the fourth transistor T4 may be NMOS. Alternatively, all transistors may be NMOS or all transistors may be PMOS.

At least one of the transistors may be a transistor having a low-temperature polycrystalline silicon (LTPS) semiconductor layer, and the rest may be transistors having oxide semiconductor layers. For example, the fifth transistor T5 may include a semiconductor layer made of polycrystalline silicon having high reliability, and each of the remaining transistors may include an oxide semiconductor layer having the characteristics of high carrier mobility and low leakage current. Below, the case where the fifth transistor T5 is a PMOS including a silicon semiconductor layer and the remaining transistors are NMOS including an oxide semiconductor layer is described.

The sub-pixel circuit PC may be electrically connected to gate lines that transmit signals to the gate electrodes of each of the transistors. For example, the sub-pixel circuit PC may be connected to a scan line GWL that transmits a scan signal GW, an initialization gate line GBL that transmits an initialization signal GB, a reference gate line GRL that transmits a reference signal GR, a first emission control line EML that transmits a first emission control signal EM, a second emission control line EMBL that transmits a second emission control signal EMB, and a data line DL that transmits a data signal DATA. Additionally, the sub-pixel circuit PC may be connected to a driving voltage line PL that transmits a driving voltage ELVDD, a reference voltage line VRL that transmits a reference voltage VREF, and an initialization voltage line VL that transmits an initialization voltage VINT.

The first transistor T1, which is a driving transistor, may be electrically connected between the driving voltage line PL and a second node N2. The first transistor T1 may include a first gate electrode G1 connected to a first node N1, the first terminal electrically connected to the driving voltage line PL, and the second terminal connected to the second node N2. The first terminal may be a drain region and the second terminal may be a source region. The first terminal of the first transistor T1 may be electrically connected to the driving voltage line PL via the fifth transistor T5, and the second terminal of the first transistor T1 may be electrically connected to a pixel electrode of a light-emitting diode LED. The first transistor T1 may receive the data signal DATA according to a switching operation of the second transistor T2 and control an amount of driving current Id flowing to the light-emitting diode LED.

The second transistor T2, which is a data writing transistor, may be electrically connected between the data line DL and the first node N1. The second transistor T2 may include a gate electrode connected to the scan line GWL, the first terminal connected to a data line DL, and the second terminal connected to the first node N1. The second transistor T2 is turned on by the scan signal GW transmitted to the scan line GWL to electrically connect the data line DL and the first node N1, thereby transmitting the data signal DATA from the data line DL to the first node N1.

The third transistor T3, which is a first initialization transistor, may be electrically connected between the first node N1 and the reference voltage line VRL. The third transistor T3 may include a gate electrode connected to a reference gate line GRL, the first terminal connected to the first node N1, and the second terminal connected to the reference voltage line VRL. The third transistor T3 is turned on by the reference signal GR transmitted to the reference gate line GRL, and may transmit the reference voltage VREF from the reference voltage line VRL to the first node N1.

The fourth transistor T4, which is a second initialization transistor, may be electrically connected between the first transistor T1 and the initialization voltage line VL. The fourth transistor T4 may include a gate electrode connected to the gate line GBL, a second terminal of the sixth transistor T6 and the first terminal connected to the light-emitting diode LED, and the second terminal connected to the initialization voltage line VL. The fourth transistor T4 is turned on by the initialization signal GB transmitted to the initialization gate line GBL, and may transmit the initialization voltage VINT from the initialization voltage line VL to a pixel electrode of the light-emitting diode LED. That is, the fourth transistor T4 may initialize the potential of the pixel electrode of the light-emitting diode LED to the initialization voltage VINT.

The fifth transistor T5, which is a light-emitting control transistor, may be electrically connected between the driving voltage line PL and the first transistor T1. The fifth transistor T5 may include a gate electrode connected to the first emission control line EML, the first terminal connected to the driving voltage line PL, and the second terminal connected to the first terminal of the first transistor T1. The fifth transistor T5 may be turned on or off according to the first emission control signal EM from the first emission control line EML.

The sixth transistor T6, which is a motion control transistor, may be connected between the first transistor T1 and the light emitting diode LED. The sixth transistor T6 may include a gate electrode connected to the second emission control line EMBL, the first terminal connected to the second node N2, and the second terminal connected to the light-emitting diode LED. The sixth transistor T6 is turned on by the second emission control signal EMB from the second emission control line EMBL, so as to electrically connect the second node N2 and the pixel electrode of the light-emitting diode LED.

For reference, FIG. 4 illustrates that the fifth transistor T5 operates in response to the first emission control signal EM and the sixth transistor T6 operates in response to the second emission control signal EMB, but the disclosure is not limited thereto. For example, the fifth transistor T5 and the sixth transistor T6 may operate in response to the same light emission control signal.

For reference, the reference signal GR may be practically synchronized with the scan signal GW of the sub-pixel circuit PC arranged in the previous row. The initialization signal GB may be practically synchronized with the scan signal GW. Alternatively, the initialization signal GB may be substantially synchronized with the scan signal GW or the reference signal GR of the sub-pixel circuit PC arranged in the next row.

The storage capacitor Cst may be electrically connected between the first node N1 and the second node N2. That is, the sub-pixel circuit PC included in the display panel according to an embodiment may be a source follower type circuit in which the storage capacitor Cst is connected between the first node N1 and the second node N2. A first storage electrode CEs1 of the storage capacitor Cst may be connected to the first node N1, and a second storage electrode CEs2 may be connected to the second node N2. The storage capacitor Cst may store a voltage corresponding to the threshold voltage of the first transistor T1 and the data signal DATA.

The hold capacitor Chd may be connected between the driving voltage line PL and the second node N2. A first hold electrode CEh1 of the hold capacitor Chd may be electrically connected to the driving voltage line PL, and a second hold electrode CEh2 may be electrically connected to the second node N2. The hold capacitor Chd may ensure that the voltage of the second node N2 of the first transistor T1 does not fluctuate and has a constant voltage when the surrounding signal fluctuates.

The light emitting diode LED includes the pixel electrode electrically connected to the second node N2 and a common electrode above the pixel electrode, and the common electrode may be supplied with the common voltage ELVSS. The common electrode may be integral to multiple light emitting diodes LEDs.

In FIG. 4, the subpixel circuit PC is illustrated as including six transistors and two capacitors, but the disclosure is not limited thereto. For example, the sub-pixel circuit PC may contain five transistors and two capacitors. It may contain seven transistors and one capacitor.

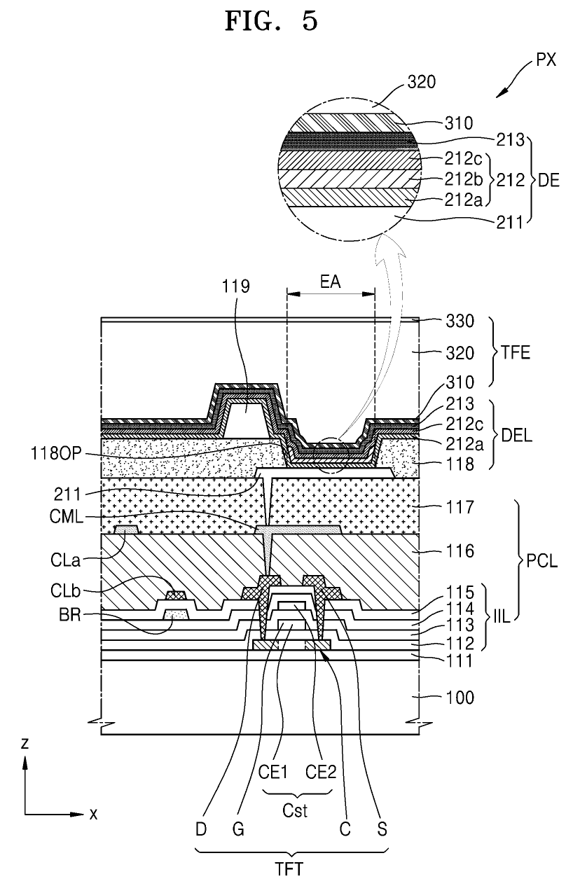

FIG. 5 is a schematic cross-sectional view of the display panel according to an embodiment.

Specifically, FIG. 5 illustrates a cross-section of one subpixel PX in a display panel, and some parts may be omitted. Hereinafter, the multilayer film laminated on the display device will be described in detail with reference to FIG. 5.

Referring to FIG. 5, the display panel may include a substrate 100, a buffer layer 111, a subpixel circuit layer PCL, a display element layer DEL, and a thin film encapsulation layer TFE.

The substrate 100 may be glass or may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. The substrate 100 including a polymer resin may have flexible, rollable, and bendable properties. The substrate 100 may have a multilayer structure including a base layer containing the aforementioned polymer resin and a barrier layer (not shown).

The buffer layer 111 may include an inorganic insulating material such as silicon nitride, silicon oxynitride, and silicon oxide, and may be a single layer or multilayer including the aforementioned inorganic insulating material.

The subpixel circuit layer PCL may be disposed on the buffer layer 111. The subpixel circuit layer PCL may include a thin film transistor TFT included in the sub-pixel circuit and an inorganic insulating layer IIL disposed below and/or above the components of the thin film transistor TFT, a first planarization layer 116, and a second planarization layer 117. The inorganic insulating layer IIL may include a first gate insulating layer 112, a second gate insulating layer 113, a third gate insulating layer 114, and an interlayer insulating layer 115.

The thin film transistor TFT includes a semiconductor layer C, and the semiconductor layer C may include polysilicon. Alternatively, the semiconductor layer C may include amorphous silicon, an oxide semiconductor, an organic semiconductor, etc. The semiconductor layer C may include a channel region and a drain region and a source region respectively arranged on both sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), etc., and may be formed as a multilayer or single layer including the above materials.

The first gate insulating layer 112 between the semiconductor layer C and the gate electrode G may include an inorganic insulating material such as silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2).

The second gate insulating layer 113 may be provided to cover the gate electrode G. The second gate insulating layer 113 may, similarly to the first gate insulating layer 112, include an inorganic insulating material such as silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2).

An upper electrode CE2 of a storage capacitor Cst may be placed on the second gate insulating layer 113. The upper electrode CE2 may overlap the gate electrode G under it. At this time, the gate electrode G and the upper electrode CE2 overlapping with the second gate insulating layer 113 in between may form the storage capacitor Cst of the subpixel circuit. That is, the gate electrode G may function as the lower electrode CE1 of the storage capacitor Cst. In this way, the storage capacitor Cst and the thin film transistor TFT may be formed by overlapping each other. In some embodiments, the storage capacitor Cst may be formed so as not to overlap the thin film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the aforementioned materials.

The third gate insulating layer 114 may cover the upper electrode CE2. The third gate insulating layer 114 may include silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2). The third gate insulating layer 114 may be a single layer or multilayer including the aforementioned inorganic insulating material.

A bridge line BR may be disposed on the third gate insulating layer 114. The interlayer insulation layer 115 may cover the bridge line BR. The interlayer insulating layer 115 may include silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2). The interlayer insulating layer 115 may be a single layer or multiple layers including the aforementioned inorganic insulating material.

A drain electrode D, a source electrode S, and a data line DL may each be disposed on the interlayer insulating layer 115. The drain electrode D, the source electrode S, and the data line DL may include a material having good conductivity. The drain electrode D, the source electrode S, and the data line DL may include a conductive material including molybdenum (Mo), aluminum (Al), copper (Cu), titanium (Ti), etc., and may be formed as a multilayer or single layer including the above materials. In one embodiment, the drain electrode D, the source electrode S, and the data line DL may have a multilayer structure of Ti/Al/Ti.

The first planarization layer 116 may be disposed to cover the drain electrode D, the source electrode S, and a vertical connection line CLb. The first flattening layer 116 may include an organic insulating layer. The first flattening layer 116 may include an organic insulator such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

A connection electrode CML and a horizontal connection line CLa may be disposed on the first flattening layer 116. At this time, the connection electrode CML may be connected to the drain electrode D or the source electrode S through a contact hole of the first planarization layer 116. The connecting electrode CML and a connection line CL may include a material having good conductivity. The connecting electrode CML and the connection line CL may include a conductive material including molybdenum (Mo), aluminum (Al), copper (Cu), titanium (Ti), etc., and may be formed of a multilayer or single layer including the above materials. In one embodiment, the connection electrode CML and the connection line CL may have a multilayer structure of Ti/Al/Ti.

The second flattening layer 117 may be disposed to cover the horizontal connecting line CLa and the connection electrode CML. The second flattening layer 117 may include an organic insulating layer. The second flattening layer 117 may include an organic insulator such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

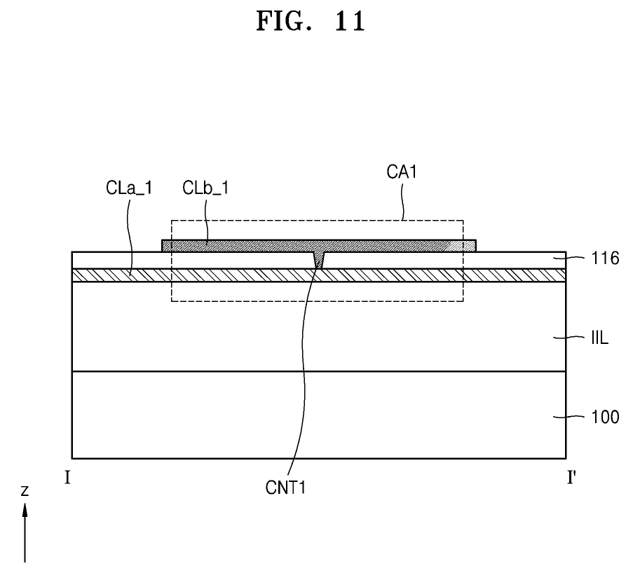

The display element layer DEL may be disposed on the pixel circuit layer PCL. The display element layer DEL may include a display element DE. The display element DE may be an organic light emitting diode OLED. A pixel electrode 211 of the display element DE may be electrically connected to the connection electrode CML through a contact hole of the second planarization layer 117. In FIG. 11, the pixel electrode 211 of the display element DE is illustrated as being electrically connected to the thin film transistor TFT through the connection electrode CML, but the connection electrode CML may be omitted and the pixel electrode 211 of the display element DE may be directly connected to the thin film transistor TFT.

The pixel electrode (211) may include a conductive oxide such as indium tin oxide (ITO), indium zinc oxide (IZO), zinc oxide (ZnO), indium oxide (In2O3), indium gallium oxide (IGO), or aluminum zinc oxide (AZO). In another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the pixel electrode 211 may further include a film formed of ITO, IZO, ZnO or In2O3 above/below the aforementioned reflective film.

A pixel definition film 118 having an opening 118OP exposing the central portion of the pixel electrode 211 may be disposed on the pixel electrode 211. The pixel definition film 118 may include an organic insulating material and/or an inorganic insulating material. The opening 118OP may define an emission area (hereinafter referred to as emission area) EA of light emitted from the display element DE. For example, a width of the opening 118OP may correspond to a width of the light-emitting area EA of the display element DE.

A spacer 119 may be disposed on the pixel definition film 118. The spacer 119 may be used to prevent damage to the substrate 100 in a manufacturing method for a display device. When manufacturing a display panel, a mask sheet may be used. At this time, when the mask sheet enters the opening 118OP of the pixel definition film 118 or is in close contact with the pixel definition film 118 to deposit a material on the substrate 100, a defect in which a part of the substrate 100 is damaged or broken by the mask sheet may be prevented.

The spacer 119 may include an organic insulating material such as polyimide. Alternatively, the spacer 119 may include an inorganic insulator such as silicon nitride or silicon oxide, or may include an organic insulator and an inorganic insulator.

In one embodiment, the spacer 119 may comprise a different material than the pixel definition film 118. Alternatively, in another embodiment, the spacer 119 may include the same material as the pixel definition film 118, in which case the pixel definition film 118 and the spacer 119 may be formed together in a mask process using a halftone mask or the like.

An intermediate layer 212 may be disposed on the pixel definition film 118. The intermediate layer 212 may include a light-emitting layer 212b disposed in the opening 118OP of the pixel definition film 118. The light-emitting layer 212b may include a polymer or low-molecular organic material that emits light of a predetermined color.

A first functional layer 212a and a second functional layer 212c may be disposed above and below the light-emitting layer 212b, respectively. The first functional layer 212a may include, for example, a hole transport layer HTL or a hole transport layer and a hole injection layer HIL. The second functional layer 212c is a component disposed on the light-emitting layer 212b and may be optional. The second functional layer 212c may include an electron transport layer ETL and/or an electron injection layer EIL. The first functional layer 212a and/or the second functional layer 212c may be a common layer formed to cover the entire substrate 100, similar to a counter electrode 213 described below.

The counter electrode 213 may be made of a conductive material having a low work function. For example, the counter electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 213 may further include a layer such as ITO, IZO, ZnO or In2O3 on the (semi)transparent layer including the aforementioned material.

In some embodiments, a capping layer (not shown) may be further disposed on the counter electrode 213. The capping layer may include LiF, an inorganic material, and/or an organic material.

The thin film encapsulation layer TFE may be disposed on the counter electrode 213. In one embodiment, the thin film encapsulation layer TFE includes at least one inorganic encapsulation layer and at least one organic encapsulation layer, and FIG. 5 illustrates that the thin film encapsulation layer TFE includes a first inorganic encapsulation layer 310, an organic encapsulation layer 320, and a second inorganic encapsulation layer 330 that are sequentially laminated.

The first inorganic sealing layer 310 and the second inorganic sealing layer 330 may include one or more inorganic materials selected from aluminum oxide, titanium oxide, tantalum oxide, hafnium oxide, zinc oxide, silicon oxide, silicon nitride, and silicon oxynitride. The organic encapsulating layer 320 may include a polymer-based material. Polymer-based materials may include acrylic resins, epoxy resins, polyimides, and polyethylene. In one embodiment, the organic encapsulating layer 320 may include acrylate.

Although not shown, a touch electrode layer may be arranged on the thin film encapsulation layer TFE, and an optical function layer may be disposed on a touch electrode layer. The touch electrode layer may obtain coordinate information according to external input, such as a touch event. The optical function layer may reduce the reflectivity of light incident from the outside toward the display device (external light) and/or improve the color purity of light emitted from the display device. In one embodiment, the optical function layer may include a retarder and/or a polarizer. The retarder may be film type or liquid crystal coating type, and may include a λ/2 phase retarder and/or a λ/4 phase retarder. The polarizer may also be film type or liquid crystal coating type. The film type may include a stretchable synthetic resin film, and the liquid crystal coating type may include liquid crystals arranged in a predetermined array. The retarder and polarizer may further include a protective film.

In another embodiment, the optical function layer may include a black matrix and color filters. The color filters may be arranged to take into account the color of light emitted from each pixel of the display device. Each of the color filters may contain red, green, or blue pigments or dyes. Alternatively, each of the color filters may further include quantum dots in addition to the pigments or dyes described above. Alternatively, some of the color filters may not contain the pigments or dyes described above, and may contain scattering particles such as titanium oxide.

In another embodiment, the optical function layer may include a destructive interference structure. The destructive interference structure may include a first reflective layer and a second reflective layer disposed on different layers. The first reflected light and the second reflected light reflected from the first reflective layer and the second reflective layer, respectively, may destructively interfere, thereby reducing the external light reflectance.

An adhesive member may be disposed between the touch electrode layer and the optical function layer. The adhesive member may be any one known in the art without limitation. The adhesive member may be a pressure sensitive adhesive PSA.

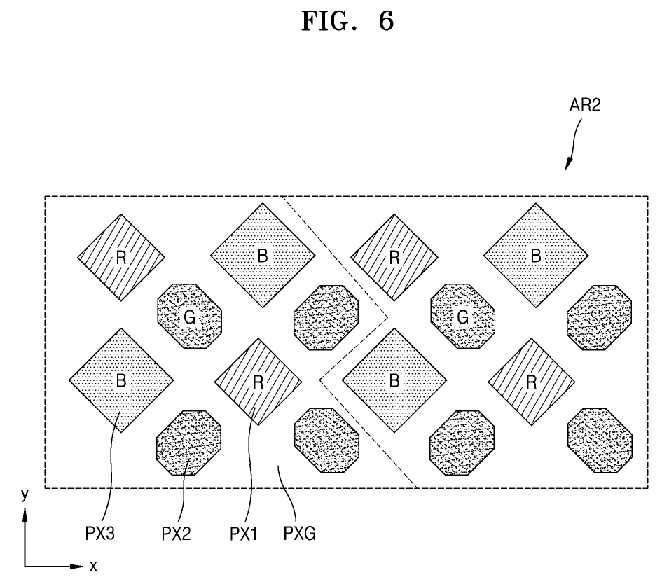

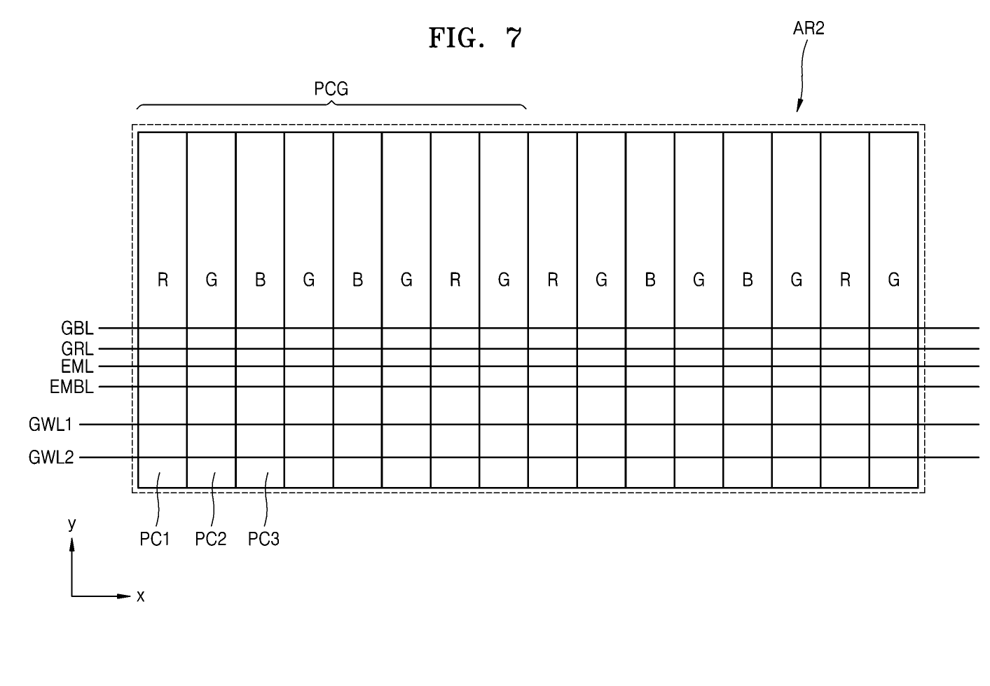

FIG. 6 is a schematic plan view of a structure in which pixels of a display panel are arranged according to an embodiment. FIG. 7 is a schematic plan view of a structure in which subpixel circuits are arranged according to an embodiment.

Referring to FIG. 6, subpixels PX may be arranged in the second area AR2 of the display panel. Although not shown, subpixels PX may also be arranged in the first area AR1 of the display panel. The subpixels PX arranged on the display panel may be arranged in a pentile arrangement (diamond arrangement).

A first subpixel PX1 may emit red light. A second subpixel PX2 may emit green light. Additionally, a third subpixel PX3 may emit blue light. However, the disclosure is not limited thereto.

A pixel unit PXG may contain eight subpixels PX. Specifically, the pixel unit PXG may include two first sub-pixels PX1, four second sub-pixels PX2, and two third sub-pixels PX3.

Referring to FIG. 7, subpixel circuits PC may be arranged in the second area AR2 of the display panel. Although not shown, subpixel circuits PC may also be arranged in the first area AR1 of the display panel. Each subpixel circuit PC electrically connected to the subpixel PX may be arranged in the first direction (e.g., in the x direction or the -x direction).

A first subpixel circuit PC1 may be electrically connected to the first subpixel PX1 that emits red light. The second subpixel circuit PC2 may be electrically connected to the second subpixel PX2 that emits green light. The third subpixel circuit PC3 may be electrically connected to the third subpixel PX3 that emits blue light.

A pixel circuit unit PCG may include subpixel circuits PCs. Specifically, the pixel circuit unit PCG may include two first subpixel circuits PC1, four second subpixel circuits PC2, and two third sub-pixel circuits PC3. The eight subpixel circuits PC illustrated in FIG. 7 may each be connected to the eight subpixels PX illustrated in FIG. 6.

The subpixel circuit PC may have a width-to-height ratio of approximately 1:8. The initialization gate line GBL, the reference gate line GRL, the first emission control line EML, the second emission control line EMBL, the reference voltage line VRL, and the initialization voltage line VL applied to one pixel circuit unit PCG may be one wire. The initialization gate line GBL, the reference gate line GRL, the first emission control line EML, the second emission control line EMBL, the reference voltage line VRL, and the initialization voltage line VL may extend in the first direction (e.g., in the x direction or the -x direction) on the display panel. The scan line GWL applied to one pixel circuit unit PCG may be two wires arranged continuously. The scan line GWL may extend in the first direction (e.g., the x direction or the -x direction) on the display panel. Although not shown, the data lines DL may each be responsible for one first subpixel PX1 and one third subpixel PX3 within one pixel circuit unit PCG, or for two second subpixels PX2 within one pixel circuit unit PCG. The data lines DL may extend in a second direction (e.g., in the y direction or the -y direction) on the display panel.

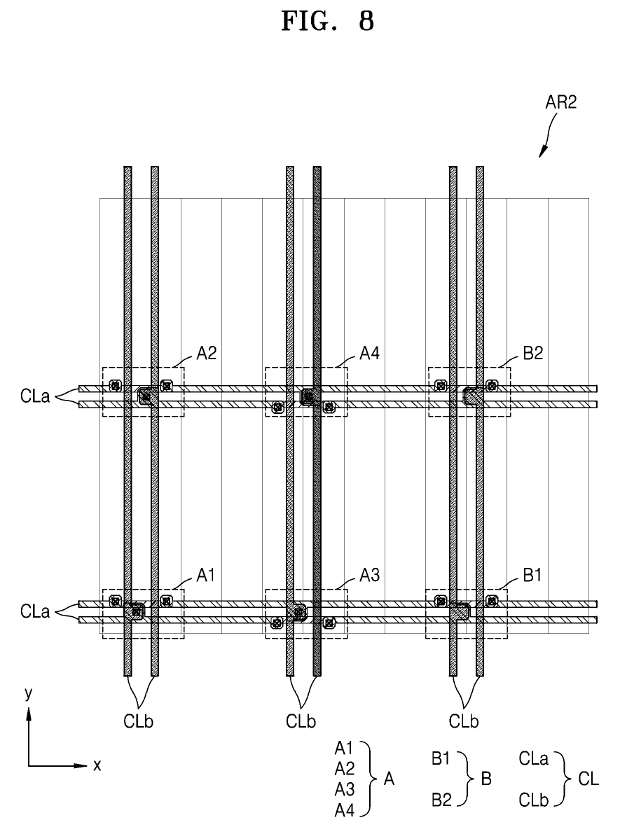

FIG. 8 is a schematic plan view of connection lines arranged in a second area of a display panel according to an embodiment.

Referring to FIG. 8, connecting lines CL may be arranged on the second area AR2 of the display panel. The connection lines CL arranged on the second area AR2 may be electrically connected to the pads arranged on the pad area PADA (see FIG. 3). In other words, data signals may be applied from pads to the connection lines CL. The connection lines CL may transmit electrical signals received from the pads to the first data line DL1 (see FIG. 3) arranged in the first region AR1 (see FIG. 3).

The connection line CL may include the horizontal connecting line CLa extending in the first direction (e.g., the x direction or the -x direction) and the vertical connecting line CLb extending in the second direction (e.g., the y direction or the -y direction). The horizontal connection lines CLa may be arranged in the second direction (e.g., in the y direction or the -y direction). The vertical connection lines CLb may be arranged in the first direction (e.g., the x direction or the -x direction).

An area where the horizontal connection line CLa and the vertical connection line CLb intersect may be a connection area A or an unconnection area B. The horizontal connection line CLa and the vertical connection line CLb may be electrically connected to each other in the connection area A. The horizontal connection line CLa and the vertical connection line CLb may not be electrically connected to each other in the unconnected area B. The connection area A may include a first connection area A1, a second connection area A2, a third connection area A3, and a fourth connection area A4. The unconnection area B may include a first unconnection area B1 and a second unconnection area B2.

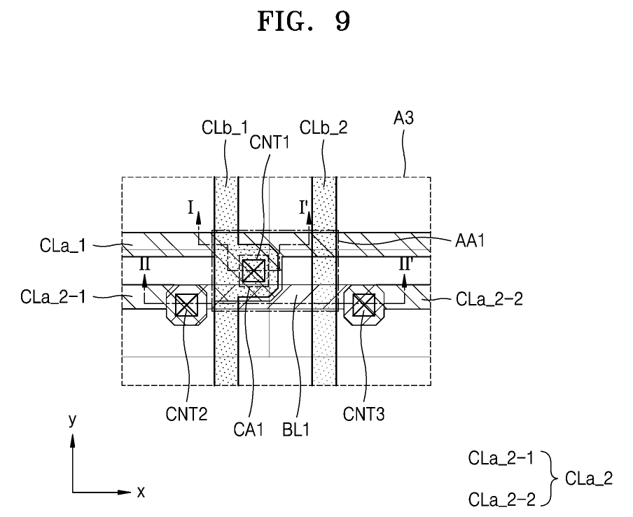

FIG. 9 is a schematic enlarged view of the third connection area illustrated in FIG. 8.

Referring to FIG. 9, a first horizontal connecting line CLa_1 may extend in the first direction (e.g., the x direction or the -x direction). A second horizontal connection line CLa_2 may include a second-first horizontal connection line CLa_2-1 and a second-second horizontal connection line CLa_2-2. The second-first horizontal connection line CLa_2-1 and the second-second horizontal connection line CLa_2-2 may extend in the first direction (e.g., the x direction or the -x direction). The first horizontal connection line CLa_1 and the second horizontal connection line CLa_2 may be arranged adjacent to each other. Specifically, no other wiring extending in the first direction (e.g., the x direction or the -x direction) may be arranged between the first horizontal connection line CLa_1 and the second horizontal connection line CLa_2.

A first vertical connection line CLb_1 may extend in the second direction (e.g., in the y direction or the -y direction). A second vertical connection line CLb_2 may extend in the second direction (e.g., in the y direction or the -y direction). The first vertical connection line CLb_1 and the second vertical connection line CLb_2 may be arranged adjacent to each other. Specifically, no other wiring extending in the second direction (e.g., the y direction or the -y direction) may be arranged between the first vertical connection line CLb_1 and the second vertical connection line CLb_2.

The first horizontal connecting line CLa_1 may include a first connection portion CA1. The first vertical connection line CLb_1 may include the first connection portion CA1. The first connection portion CA1 may be a portion in which at least a portion of the first horizontal connection line CLa_1 and at least a portion of the first vertical connection line CLb_1 overlap. In the third connection area A3, the first horizontal connection line CLa_1 and the first vertical connection line CLb_1 may be electrically connected. The first horizontal connection line CLa_1 and the first vertical connection line CLb_1 may be electrically connected through a first contact hole CNT1 arranged in the first connection portion CA1.

As described above, the first vertical connection line CLb_1 may receive a data signal from the pad arranged in the pad area PADA (see FIG. 3). The data signal applied to the first vertical connection line CLb_1 may also be applied to the first horizontal connection line CLa_1 through the first contact hole CNT1 arranged in the first connection portion CA1.

A first bridge line BL1 electrically connects the second-first horizontal connection line CLa_2-1 and the second-second horizontal connection line CLa_2-2 and may extend in the first direction (e.g., the x direction or the -x direction). The first bridge line BL1 and the second-first horizontal connection line CLa_2-1 may be electrically connected through a second contact hole CNT2, and the first bridge line BL1 and the second-second horizontal connection line CLa_2-2 may be electrically connected through a third contact hole CNT3. At least a portion of the first bridge line BL1 and the first connection portion CA1 may overlap.

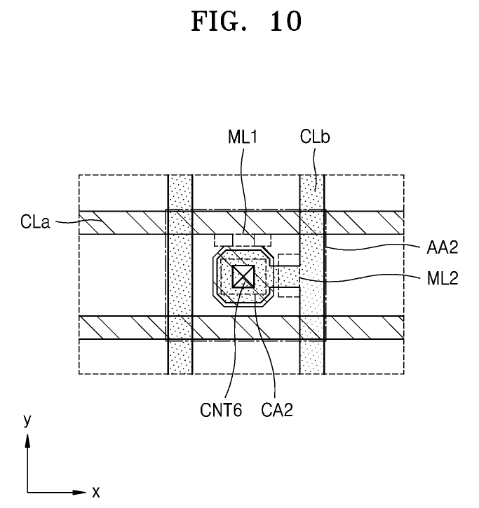

FIG. 10 is a schematic enlarged view of a connection area in a comparative example.

Referring to FIG. 10, in a comparative example, a horizontal connection line CLa extending in a first direction (e.g., the x direction or the -x direction) may include a first connection wire ML1 and a second connection portion CA2 protruding in a second direction (e.g., the y direction or the -y direction). A vertical connection line CLb extending in the second direction (e.g., in the y direction or the -y direction) may include a second connection wire ML2 and the second connection portion CA2 protruding in the first direction (e.g., in the x direction or the -x direction). The horizontal connection line CLa and the vertical connection line CLb may be electrically connected through a sixth contact hole CNT6 arranged in the second connection portion CA2. In other words, the first connection wire ML1 and the second connection wire ML2 may be required to electrically connect the horizontal connection line CLa and the vertical connection line CLb. An area of a second intersection area AA2 where the horizontal connection line CLa and the vertical connection line CLb intersect may be 190.4 ㎛².

Referring again to FIG. 9, in one embodiment, the first horizontal connection line CLa_1 and the first vertical connection line CLb_1 may be electrically connected directly through the first contact hole CNT1 arranged in the first connection portion CA1 without separate connection wiring protruding therefrom. An area of a first intersection area AA1 where the first horizontal connection line CLa_1 and the first vertical connection line CLb_1 intersect may be 69.4㎛². In comparison with the second intersection area AA2 where the horizontal connection line CLa and the vertical connection line CLb intersect in the comparative example, the area of the first intersection area AA1 where the first horizontal connection line CLa_1 and the first vertical connection line CLb_1 intersect in one embodiment may be reduced. Since the area of the first intersection area AA1 of one embodiment is smaller than that of the second intersection area AA2 of the comparative example, the space utilization of wires arranged on the display panel may be increased, and the quality and reliability of the display device may be improved.

Referring again to FIG. 8, the positions of the connection portions CA where the horizontal connecting line CLa and the vertical connecting line CLb are connected may be different in the first connection area A1, the second connection area A2, the third connection area A3, and the fourth connection area A4. By changing the position of the connection portion CA, the horizontal connection line CLa and the vertical connection line CLb may be connected without separate connection wiring, and the space utilization on the display panel may be increased, and the quality and reliability of the display device may be improved.

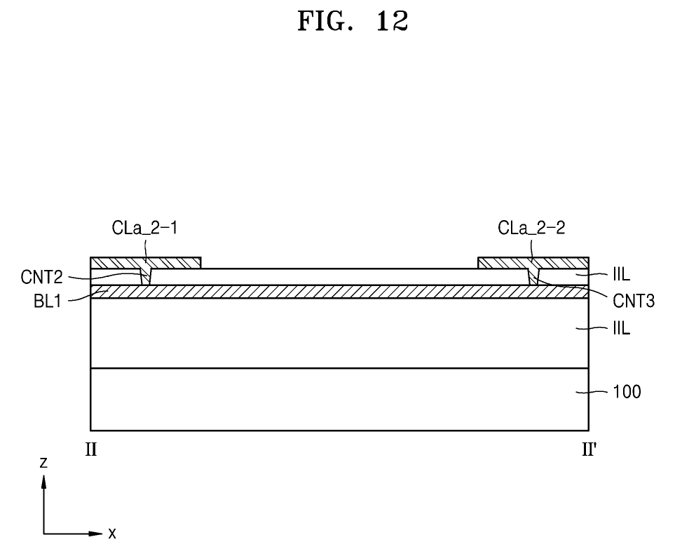

FIG. 11 is a schematic cross-sectional view of the display panel illustrated in FIG. 9 taken along line I-I'. FIG. 12 is a schematic cross-sectional view of the display panel illustrated in FIG. 9 taken along line II-II'.

Referring to FIG. 11, the first connection portion CA1 may be a portion where at least a portion of the first horizontal connection line CLa_1 and at least a portion of the first vertical connection line CLb_1 overlap. The first vertical connection line CLb_1 may be disposed above the first horizontal connection line CLa_1. Although not shown, horizontal connection lines CLa (see FIG. 8) may be disposed on a same layer and contain a same material. Additionally, vertical connecting lines CLb (see FIG. 8) may be disposed on a same layer and contain a same material.

Referring to FIG. 12, on a vertical cross-section of the substrate 100, the first bridge line BL1 may be disposed below the second-first horizontal connection line CLa_2-1 and the second-second horizontal connection line CLa_2-2.

Referring again to FIG. 9, in one embodiment, the first bridge line BL1 may overlap at least a portion of the first connection portion CA1. The first bridge line BL1 may be disposed on a different layer from the horizontal connection line CLa and the vertical connection line CLb. Specifically, the first bridge line BL1 may be disposed below the horizontal connection line CLa and the vertical connection line CLb. Since the first bridge line BL1 is disposed on a different layer from the horizontal connection line CLa and the vertical connection line CLb, the first bridge line BL1 may overlap at least a portion of the first connection portion CA1. Since the first bridge line BL1 is arranged to overlap at least a portion of the first connection portion CA1 without providing a separate space, the area of the first intersection area AA1 (see FIG. 9) of the embodiment illustrated in FIG. 9 may be reduced. By reducing the area of the first intersection area AA1, the space utilization of wires arranged on the display panel may be increased, and the quality and reliability of the display device may be improved.

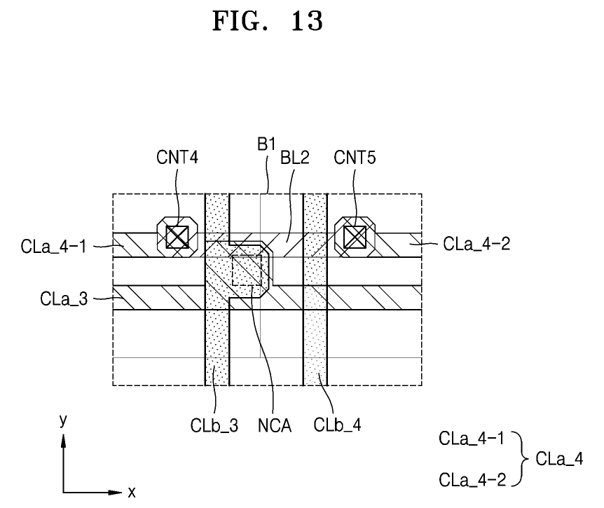

FIG. 13 is a schematic enlarged view of the first unconnection area illustrated in FIG. 8.

Referring to FIG. 13, a third horizontal connection line CLa_3 may extend in the first direction (e.g., the x direction or the -x direction). A fourth horizontal connection line CLa_4 may include a fourth-first horizontal connection line CLa_4-1 and a fourth-second horizontal connection line CLa_4-2. The fourth-first horizontal connection line CLa_4-1 and the fourth-second horizontal connection line CLa_4-2 may extend in the first direction (e.g., the x direction or the -x direction). The third horizontal connection line CLa_3 and the fourth horizontal connection line CLa_4 may be arranged adjacent to each other. Specifically, no other wiring extending in the first direction (e.g., the x direction or the -x direction) may be arranged between the third horizontal connection line CLa_3 and the fourth horizontal connection line CLa_4.

A third vertical connection line CLb_3 may extend in the second direction (e.g., in the y direction or the -y direction). A fourth vertical connection line CLb_4 may extend in the second direction (e.g., in the y direction or the -y direction). The third vertical connection line CLb_3 and the fourth vertical connection line CLb_4 may be arranged adjacent to each other. Specifically, no other wiring extending in the second direction (e.g., in the y direction or the -y direction) may be arranged between the third vertical connection line CLb_3 and the fourth vertical connection line CLb_4.

The third horizontal connection line CLa_3 may include an unconnection portion NCA. The third vertical connection line CLb_3 may include the unconnection portion NCA. The unconnection portion NCA may be a portion where at least a portion of the third horizontal connection line CLa_3 and at least a portion of the third vertical connection line CLb_3 overlap. Unlike the first connection portion CA1 (see FIG. 9) described above, a contact hole may not be arranged in the unconnection portion NCA. In the first unconnection area B1, the third horizontal connection line CLa_3 and the third vertical connection line CLb_3 may not be electrically connected.

A second bridge line BL2 electrically connects the fourth-first horizontal connection line CLa_4-1 and the fourth-second horizontal connection line CLa_4-2 and may extend in the first direction (e.g., the x direction or the -x direction). The second bridge line BL2 and the fourth-first horizontal connection line CLa_4-1 may be electrically connected through a fourth contact hole CNT4, and the second bridge line BL2 and the fourth-second horizontal connection line CLa_4-2 may be electrically connected through a fifth contact hole CNT5. At least a portion of the second bridge line BL2 and the unconnection portion NCA may overlap.

Even if the unconnection portion NCA is provided in the first unconnection area B1 and the third horizontal connection line CLa_3 and the third vertical connection line CLb_3 are not electrically connected, the density of the connection portion CA of the third connection area A3 (see FIG. 9) and the light shielding or pattern may be adjusted to be the same, thereby improving the quality and reliability of the display device. Referring again to FIG. 8, the connection areas A are provided with a connection portion CA, and the unconnection areas B are provided with an unconnection portion NCA, so that the density of light blocking or patterns in the connection areas A and the unconnection areas B may be the same, and the quality and reliability of the display device may be improved.

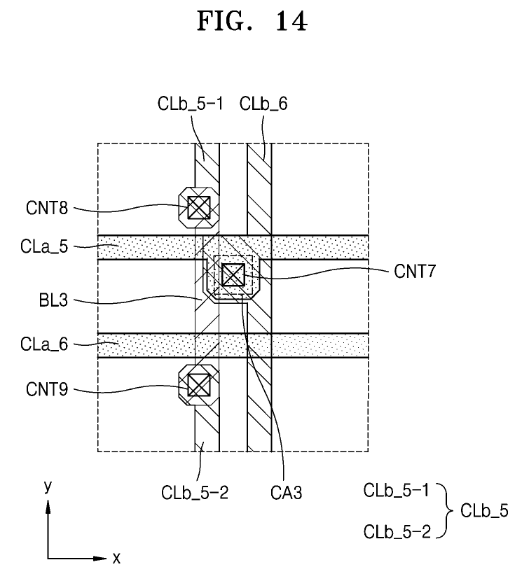

FIG. 14 is a schematic enlarged view of a connection area according to an embodiment.

Referring to FIG. 14, a fifth horizontal connecting line CLa_5 may extend in the first direction (e.g., the x direction or the -x direction). A sixth horizontal connection line CLa_6 may extend in the first direction (e.g., the x direction or the -x direction). The fifth horizontal connection line CLa_5 and the sixth horizontal connection line CLa_6 may be arranged adjacent to each other. Specifically, no other wiring extending in the first direction (e.g., the x direction or the -x direction) may be arranged between the fifth horizontal connection line CLa_5 and the sixth horizontal connection line CLa_6.

The fourth vertical connection line CLb_4 may extend in the second direction (e.g., in the y direction or the -y direction). A fifth vertical connecting line CLb_5 may include a fifth-first vertical connection line CLb_5-1 and a fifth-second vertical connection line CLb_5-2. The fifth-first vertical connection line CLb_5-1 and the fifth-second vertical connection line CLb_5-2 may extend in the second direction (e.g., the y direction or the -y direction). The fourth vertical connection CLb_4 and the fifth vertical connection line CLb_5 may be arranged adjacent to each other. Specifically, no other wiring extending in the second direction (e.g., in the y direction or the -y direction) may be arranged between the fourth vertical connection line CLb_4 and the fifth vertical connection line CLb_5.

The fifth horizontal connection line CLa_5 may include a third connection portion CA3. A sixth vertical connection line CLb_6 may include the third connection portion CA3. The third connection portion CA3 may be a portion in which at least a portion of the fifth horizontal connection line CLa_5 and at least a portion of the sixth vertical connection line CLb_6 overlap. The fifth horizontal connection line CLa_5 and the sixth vertical connection line CLb_6 may be electrically connected through a seventh contact hole CNT7 arranged in the third connection portion CA3.

As described above, the sixth vertical connection line CLb_6 may receive the data signal from the pad arranged in the pad area PADA (see FIG. 3). The data signal applied to the sixth vertical connection line CLb_6 may also be applied to the fifth horizontal connection line CLa_5 through the seventh contact hole CNT7 arranged in the third connection portion CA3.

A third bridge line BL3 electrically connects the fifth-first vertical connection line CLb_5-1 and the fifth-second vertical connection line CLb_5-2 and may extend in the second direction (e.g., the y direction or the -y direction). The third bridge line BL3 and the fifth-first vertical connection line CLb_5-1 may be electrically connected through a eigth contact hole CNT8, and the third bridge line BL3 and the fifth-second vertical connection line CLb_5-2 may be electrically connected through a ninth contact hole CNT9. At least a portion of the third bridge line BL3 and the third connection portion CA3 may overlap.

According to one embodiment as described above, the display device with improved reliability and quality and the electronic device including the same may be implemented in any electronic device.

Although the present display device has been described with reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

What is claimed is:

1. A display device, comprising:
a display panel comprising a substrate;
a first horizontal connection line disposed on the substrate, extending in a first direction, and including a first connection portion;
a first vertical connection line disposed on the substrate, extending in a second direction intersecting the first direction and including the first connection portion;
a second horizontal connection line disposed on the substrate adjacent to the first horizontal connection line, the second horizontal connection line comprising a second-first horizontal connection line and a second-second horizontal connection line, the second-first horizontal connection line and the second-second horizontal connection line extending in the first direction; and
a first bridge line electrically connecting the second-first horizontal connection line to the second-second horizontal connection line, wherein
the first horizontal connection line and the first vertical connection line are electrically connected to each other through a first contact hole in the first connection portion.

2. The display device of claim 1, wherein
the first connection portion comprises a portion where at least a portion of the first horizontal connection line and at least a portion of the first vertical connection line overlap.

3. The display device of claim 1, wherein
a data signal is applied to the first vertical connection line.

4. The display device of claim 3, wherein
the data signal applied to the first vertical connection line is also applied to the first horizontal connection line through the first contact hole.

5. The display device of claim 1, wherein
the first bridge line overlaps at least a portion of the first connection portion.

6. The display device of claim 1, wherein
the first bridge line and the second-first horizontal connection line are electrically connected to each other through a second contact hole.

7. The display device of claim 1, wherein
the first bridge line and the second-second horizontal connection line are electrically connected to each other through a third contact hole.

8. The display device of claim 1,
further comprising a pixel unit disposed on the substrate and including eight subpixels.

9. The display device of claim 8, wherein
the eight subpixels included in the pixel unit are arranged in a pentile array.

10. The display device of claim 8, wherein
each subpixel circuit of eight subpixel circuits is respectively electrically connected to a subpixel of the eight subpixels included in the pixel unit, and the eight subpixels are arranged in the first direction.

11. The display device of claim 1, further comprising:
a third horizontal connection line disposed on the substrate, extending in the first direction, and including a unconnected portion;
a second vertical connection line disposed on the substrate, extending in the second direction and including the unconnected portion;
a fourth horizontal connection line disposed on the substrate adjacent to the third horizontal connection line, the fourth horizontal connection line comprising a fourth-first horizontal connection line and a fourth-second horizontal connection line, the fourth-first horizontal connection line and the fourth-second horizontal connection line extending in the first direction; and
a second bridge line electrically connecting the fourth-first horizontal connection line to the fourth-second horizontal connection line.

12. The display device of claim 11, wherein
the unconnected portion is a portion where at least a portion of the third horizontal connection line and at least a portion of the second vertical connection line overlap each other.

13. The display device of claim 11, wherein
the second bridge line overlaps at least a portion of the unconnected portion.

14. The display device of claim 11, wherein
the second bridge line and the fourth-first horizontal connection line are electrically connected to each other through a fourth contact hole.

15. The display device of claim 11, wherein
the second bridge line and the fourth-second horizontal connection line are electrically connected to each other through a fifth contact hole.

16. An electronic device, comprising:
a display panel; and
a lower cover forming an exterior of the electronic device and having an opening exposing a portion of the display panel on a front surface,
the display panel comprising:
a substrate;
a first horizontal connection line disposed on the substrate, extending in the first direction, and including a first connection portion;
a first vertical connection line disposed on the substrate, extending in the second direction intersecting the first direction and including the first connection portion;
a second vertical connection line disposed on the substrate comprising a second-first vertical connection line and a second-second vertical connection line, and the second vertical connection line being adjacent to the first vertical connection line, and the second vertical connection line extending in the second direction; and
a first bridge line electrically connecting the second-first vertical connection line to the second-second vertical connection line, wherein
the first horizontal connection line and the first vertical connection line are electrically connected to each other through a first contact hole arranged in the first connection portion.

17. The electronic device of claim 16, wherein
the first connection portion is a portion where at least a portion of the first horizontal connection line and at least a portion of the first vertical connection line overlap.

18. The electronic device of claim 16, wherein
a data signal is applied to the first vertical connection line, and
the data signal applied to the first vertical connection line is also applied to the first horizontal connection line through the first contact hole.

19. The electronic device of claim 16, wherein
the first bridge line and the second-first vertical connection line are electrically connected through a second contact hole.

20. The electronic device of claim 16, wherein
the first bridge line and the second-second vertical connection line are electrically connected to each other through an third contact hole.
